(19) United States
(12) Patent Application Publication
(10) Pub. No.: US 2013/0313013 A1
(43) Pub. Date: Nov. 28, 2013

(54) PRINTED CIRCUIT BOARDS

(71) Applicants: DAVID SALA PORTA, (US); David Soriano Fosas, Terrassa (ES); Juan Luis López Rodriguez, Subirats (ES)

(72) Inventors: DAVID SALA PORTA, (US); David Soriano Fosas, Terrassa (ES); Juan Luis López Rodriguez, Subirats (ES)

(21) Appl. No.: 13/478,465

(22) Filed: May 23, 2012

(51) Int. Cl. H05K 1/02

(52) U.S. Cl. 174/268

(57) ABSTRACT

A printed circuit board comprises at least one microstrip transmission line with a conductive solid reference plane and at least one conductive trace embedded in a dielectric substrate, and further comprises at least one conductive shielding layer having a lattice structure, wherein the conductive trace is arranged between the solid reference plane and the shielding layer.

In the field of printed circuit boards (PCB), and more particularly high speed PCBs, it is known to employ transmission lines with microstrip technology, i.e. comprising an asymmetric structure in which a conductive trace is embedded in a dielectric substrate with a conductive reference plane, such as a ground plane, arranged on one side.

A drawback of such microstrip transmission lines is that they are more subject to interference due to external electromagnetic radiation than transmission lines with stripline technology, which involve a symmetric structure in which the conductive trace has conductive reference planes on both sides: the two conductive planes can shield the transmission line from radiation.

Another aspect that needs to be considered in relation to a microstrip transmission line is that a consistent impedance of the line may be an important issue: it may be desirable to avoid large variations of the impedance of the line, in order to preserve the signal integrity of high speed signals.

The impedance of the line depends on multiple factors such as the geometry of the conductive trace, the dielectric constant of the surrounding material, and the number of ground reference planes. Consequently, although placing a further ground plane over the conductive trace, as in a stripline structure, would have a shielding effect, it would also affect the impedance of the line, and may therefore not be a satisfactory solution.

One known solution to protect PCBs with microstrip transmission lines from external radiation is to employ an external metal housing electrically connected to ground and arranged at a distance from the PCB. Such an external housing or shield is efficient against radiation, and does not significantly affect the impedance of the line because the distance between the line and the shield is large enough to avoid electromagnetic coupling.

However, this solution is not always convenient due to its relatively high cost, and especially because there are parts of a PCB on which an external shield cannot be placed, for example because of the presence of connectors that need to be accessible.

In printed circuit boards according to examples of the present invention the protection against electromagnetic radiation is improved, while the impedance of the transmission lines is not significantly affected.

Some non-limiting examples will be described in the following with reference to the appended drawings, in which:

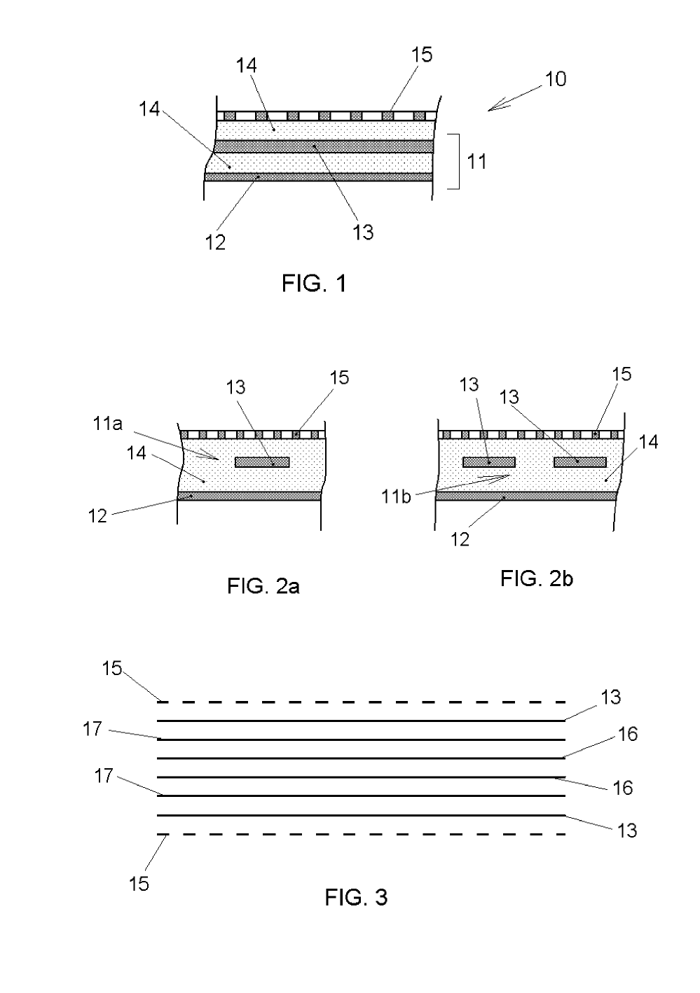

FIG. 1 shows schematically an example of a printed circuit board structure, in cross section taken in the direction of a transmission line;

FIGS. 2a and 2b show schematically examples of printed circuit boards for a single ended and a differential line, respectively, in cross section in a direction at right angles to the direction of the transmission lines;

FIG. 3 shows schematically another example of the structure of a printed circuit board;

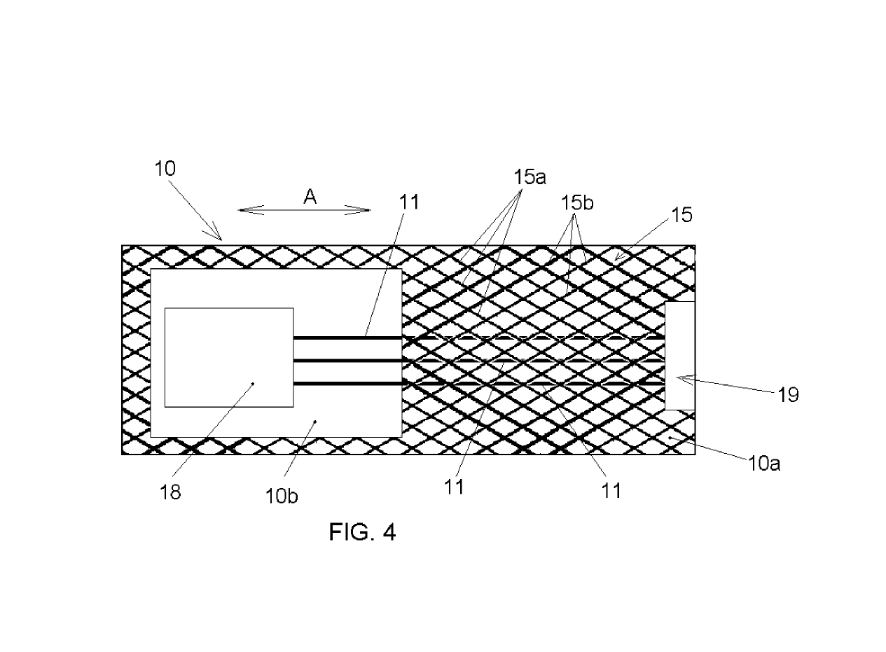

FIG. 4 shows schematically a further example of a printed circuit board;

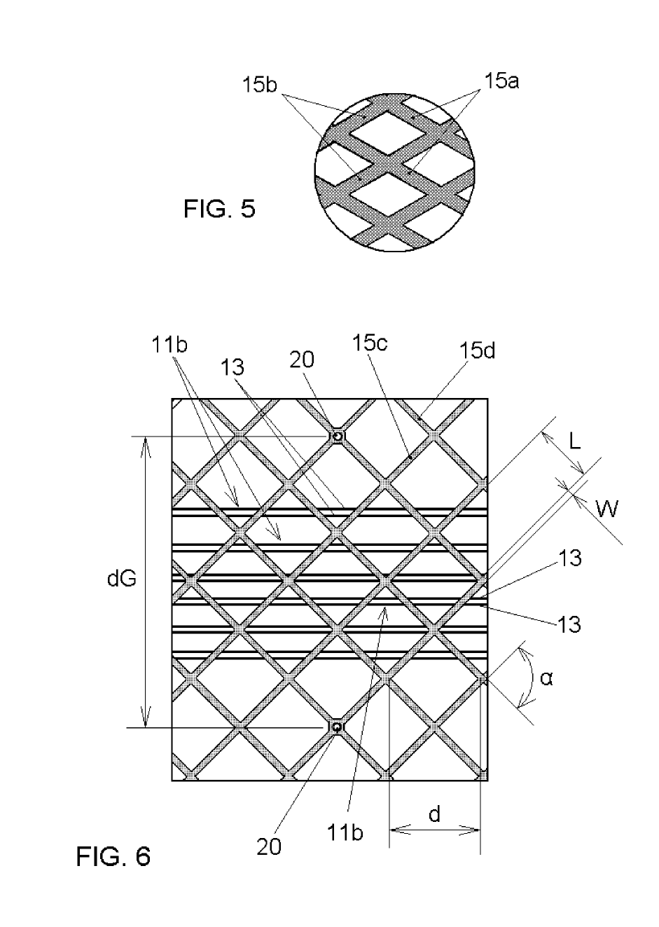

FIG. 5 shows an enlarged portion of a lattice structure according to an example, and

FIG. 6 shows an enlarged portion of a lattice structure according to another example.

As shown in FIG. 1, in one example a printed circuit board (PCB) 10 comprises a microstrip transmission line 11: the transmission line comprises a conductive solid reference plane 12, a conductive trace 13 for signal transmission, and a dielectric substrate 14 in which the conductive trace 13 is embedded.

The PCB further comprises a conductive shielding layer 15 having a lattice structure, which may be electrically connected to ground and is arranged such that the conductive trace 13 is set between the solid reference plane 12 and the shielding layer 15.

The shielding layer 15 may be the outermost conductive layer of the PCB, and there may be an insulating solder mask over the conductive shielding layer.

By conductive solid reference plane it is meant herein a layer of the printed circuit board made of an electrically conductive material and having substantially no openings or voids, other than the necessary vias or through-hole paths to other surfaces of the PCB, mounting holes, or the like. The reference plane may be a ground plane, or other voltage reference plane.

With a structure such as that of FIG. 1 the transmission line is relatively protected from electromagnetic radiation, because the lattice structure of the shielding layer may reflect back a large proportion of the electromagnetic waves to which the top side of the PCB may be exposed; and at the same time the shielding layer is suitable to avoid a relevant alteration of the line impedance.

Indeed, the lattice structure can be arranged such that its lines don't run in parallel with the transmission line for relevant lengths, and only coincide with the transmission line at discrete crossing points (at different levels), such that electromagnetic coupling affecting the impedance may largely be avoided.

Providing the PCB with a shielding layer that avoids relevant alterations of the line impedance allows for example to provide a PCB having areas where the transmission line is shielded with an external housing or shield combined with areas in which the shielding is incorporated in the PCB itself, without giving up electromagnetic protection.

FIGS. 2a and 2b show respectively examples of PCBs with a single ended transmission line 11a, with one conductive trace 13, and with a differential transmission line 11b, with two parallel conductive traces 13 arranged at a distance, embedded in a dielectric 14. In both cases there may be a solid reference plane 12 on one side the transmission line 11a, 11b and a shielding layer 15 having a lattice structure.

FIG. 3 shows a further example of a PCB, in this case a multi-layer PCB having several reference planes and two layers of conductive traces, forming microstrip transmission lines. The dielectric layers that would be present between the conductive layers have been omitted from the figure, which is only a schematic representation of the layer structure of the PCB.

In the PCB structure shown in FIG. 3, for example, the deepest conductive layers may be two power planes 16; towards each side there may then be a ground plane 17 and a conductive trace 13 to transmit signals, and finally the outermost conductive layers on each side of the PCB may be shielding layers 15 having a lattice structure.

The lattice structure of each shielding layer 15 may be connected to ground; for example, it may be connected to the adjacent ground plane 17 through a number of vias (not shown in FIG. 3).

FIG. 4 shows an example of a shielding layer having a lattice structure, in a PCB having three transmission lines 11. The figure is a very schematic plan view, and is only meant to show an example of the configuration of the lattice structure and its relative position with respect to the transmission lines.

Transmission lines in a PCB may comprise bends in order to extend between two intended positions without crossing, but in general they may have a principal direction. As shown in the figure, the transmission lines 11 have in this case a principal direction indicated by arrow A.

The transmission lines 11 shown in this example extend from a high speed device 18, such as a microprocessor, and a connector 19.

The lattice structure of the shielding layer 15 may comprise conductors that extend in directions that are not coincident with said principal direction A of the transmission lines 11, as shown by lines 15a, 15b.

In some examples, such as shown, the lattice structure 15 may comprise two sets of parallel conductors, which may be straight lines 15a and 15b, one set 15a being arranged at an angle with respect to the other set 15b, forming a grid as shown in FIG. 5.

FIG. 6 shows another example of the geometry of a lattice structure of a shielding layer 15 comprising two sets of parallel conductors, 15c and 15d arranged at an angle with respect to each other, in a PCB comprising differential microstrip transmission lines.

FIG. 6 shows the relative position of the lattice structure and of a number of differential signal transmission lines 11b of the PCB, each line comprising two conductive traces 13. Although they are shown in the figure, the transmission lines 11b are separated from the lattice structure by a layer of dielectric, as shown for example in FIG. 1 or 2.

FIG. 6 also shows an example of the position of two connections 20 (for example vias) between the lattice structure and an underlying ground plane, provided in order to ground the lattice structure. Connections 20 such as those shown in FIG. 6 may be present on substantially all the extension of the lattice structure of the shielding layer.

In examples of PCBs as described herein, the geometry of the lattice structure of the shielding layer may depend on the frequencies to be shielded; the lattice may be designed to have a maximum aperture (dimension d in FIG. 6) that is smaller than or comparable to the shortest wavelength of the electromagnetic radiation from which the PCB needs to be shielded.

On the other hand, the distance between connections 20 (shielding layer to ground plane) may be at least six times smaller than the shorter wavelength of the signals to be transmitted, in order to preserve signal integrity.

The features of the lattice structure of an example such as that of FIG. 6 may be as follows:
Trace width: W=0.254 mm (10 mil)
Side length: L=2.2 mm (88.38 mil)
Angle: α=90°
Maximum aperture: d=3.125 mm (125 mil)
Distance between connections: dG=9.375 mm (375 mil)

In the example of FIG. 6, other features of the PCB may be as follows:
Angle between the lines of the lattice and the transmission lines is 45°.
Trace width of the differential transmission line: 0.1 mm (4 mil)
Trace spacing of the differential transmission line: 0.1 mm (4 mil)
Distance between shielding layer and transmission line: 0.1 mm (4 mil)
Distance between reference plane and transmission line: 0.1 mm (4 mil).

With this geometry, the lattice may shield the transmission lines from external electromagnetic radiation having wavelengths λ=3.125 mm or higher.

Regarding the impedance of the transmission lines, and simplifying assuming that crossings between the lattice and the transmission lines are orthogonal, each crossing takes up about a trace width, i.e. 0.254 mm; since in the worst case there are two crossings for each square of the lattice, i.e. for each distance d of 3.125 mm, the proportion of the line that may be subject to coupling with the lattice is (2×0.254/3.125)×100=16.3%. The impedance may thus be affected only in a relatively small degree by the shielding layer.

The shielding layer 15 with a lattice structure may be made of copper, like other conductive parts of the PCB.

Returning to FIG. 4, this figure also shows schematically an example of the position of the shielding layer having a lattice structure on the PCB: as shown, the conductive shielding layer 15 having a lattice structure may extend on only a portion 10a of the printed circuit board 10, leaving a portion 10b free from the shielding layer.

The unshielded portion 10b of the PCB 10 may be a portion where there is no connectors, and that can be shielded by providing a shielding housing external to the PCB: for example, an area where a high speed device 18 is arranged, an area with no transmission lines, or other.

Although only a number of particular examples have been disclosed herein, further variants and modifications of the disclosed print media products are possible; other combinations of the features of embodiments or examples described are also possible. The scope of the present invention should not be limited by particular examples, but should be determined only by a fair reading of the claims that follow.

1. A printed circuit board comprising at least one microstrip transmission line, said microstrip transmission line comprising a conductive solid reference plane and at least one conductive trace embedded in a dielectric substrate, the printed circuit board further comprising at least one conductive shielding layer having a lattice structure, wherein the conductive trace is arranged between the solid reference plane and the shielding layer.

2. A printed circuit board as claimed in claim 1, wherein the conductive shielding layer having a lattice structure is the outermost conductive layer of the printed circuit board.

3. A printed circuit board as claimed in claim 1, comprising two conductive shielding layers having a lattice structure, one on each side of the printed circuit board.

4. A printed circuit board as claimed in claim 1, wherein the lattice structure of the conductive shielding layer comprises two sets of straight lines, the lines in each set being parallel, and the two sets of straight lines being arranged on the printed circuit board at an angle to each other.

5. A printed circuit board as claimed in claim 4, wherein the conductive trace of the microstrip transmission line in the printed circuit board has a principal direction, and the straight lines of the lattice structure of the conductive shielding layer are arranged at an angle with respect to this principal direction.

6. A printed circuit board as claimed in claim 1, further comprising a plurality of electrical connections between the shielding layer and a reference plane.

7. A printed circuit board as claimed in claim 1, further comprising a plurality of electrical connections between the shielding layer and a ground plane.

8. A printed circuit board as claimed in claim 7, wherein the electrical connections between the shielding layer and a ground plane are arranged at a distance from each other that is at least six times smaller than the shortest wavelength to be transmitted in the transmission line.

9. A printed circuit board as claimed in claim 1, wherein the geometry of the lattice structure of the shielding layer depends on the frequencies to be shielded.

10. A printed circuit board as claimed in claim 9, wherein the lattice structure comprises a maximum aperture that is smaller than or comparable to the shortest wavelength of the electromagnetic radiation from which the PCB needs to be shielded.

11. A printed circuit board as claimed in claim 1, wherein the microstrip line is a single ended microstrip line, comprising one conductive trace.

12. A printed circuit board as claimed in claim 1, wherein the microstrip line is a differential microstrip line, comprising two parallel conductive traces.

13. A printed circuit board as claimed in claim 1, further comprising an insulating solder mask over the conductive shielding layer having a lattice structure.

14. A printed circuit board as claimed in claim 1, wherein the conductive solid reference plane is a ground or power plane.

15. A printed circuit board as claimed in claim 1, wherein the conductive shielding layer having a lattice structure extends on only a portion of the printed circuit board.

16. A printed circuit board comprising a conductive solid reference plane, a shielding layer, and a transmission line for high speed signal transmission arranged between the reference plane and the shielding layer, wherein the shielding layer comprises two sets of parallel conductors, one set of parallel conductors being arranged at an angle with respect to the other set, forming a grid.

17. A printed circuit board comprising a transmission line embedded in a dielectric substrate and having a principal direction, a conductive solid reference plane arranged on one side of the transmission line, and a conductive shielding layer having a lattice structure arranged on the other side of the transmission line, the lattice structure comprising conductors that extend in directions that are not coincident with said principal direction of the transmission line.
